(19) United States
(12) Patent Application Publication
(10) Pub. No.: US 2021/0047724 A1
(43) Pub. Date: Feb. 18, 2021

(54) FILM FORMING APPARATUS AND FILM FORMING METHOD

(71) Applicant: Tokyo Electron Limited, Tokyo (JP)

(72) Inventors: Syuji NOZAWA, Nirasaki City (JP); Tatsuya YAMAGUCHI, Nirasaki City (JP); Makoto FUJIKAWA, Nirasaki City (JP)

(21) Appl. No.: 16/992,550

(22) Filed: Aug. 13, 2020

(30) Foreign Application Priority Data
Aug. 16, 2019 (JP) 2019-149459

(51) Int. Cl. C23C 14/54; C23C 14/00; C23C 14/22

(52) U.S. Cl. CPC C23C 14/542; C23C 14/228; C23C 14/0063

(57) ABSTRACT

There is provided a film forming apparatus including: a processing container whose interior is kept in a vacuum atmosphere; a stage provided within the processing container and configured to place a substrate thereon; a first film-forming gas supply part configured to supply a first film-forming gas for forming an organic film on a member within the processing container; a second film-forming gas supply part configured to supply a second film-forming gas for forming a film on the substrate; and a modifying gas supply part configured to supply a modifying gas for modifying the organic film and to suppress a film from being formed on a surface of the organic film by the second film-forming gas.

### CROSS-REFERENCE TO RELATED APPLICATION

This application is based upon and claims the benefit of priority from Japanese Patent Application No. 2019-149459, filed on Aug. 16, 2019, the entire contents of which are incorporated herein by reference.

### TECHNICAL FIELD

The present disclosure relates to a film forming apparatus and a film forming method.

### BACKGROUND

In a process of manufacturing a semiconductor device, there is a case in which an organic film as a polymer is formed on a semiconductor wafer (hereinafter, referred to as a “wafer”) as a substrate. Patent Document 1 discloses a film forming apparatus for forming a polyimide film as an organic film on a wafer. This film forming apparatus is provided with a container-heating part that heats a processing container, a wafer boat that holds wafers in multiple stages inside the processing container, and an inner cooling part that cools the wafer boat. The inner cooling part includes a coolant passage formed in the wafer boat and a coolant circulation part that circulates the coolant through a circulation path including the coolant passage. In order to suppress deposition of an unnecessary film on the sidewall of the processing container, a difference in temperature between the sidewall of the processing container and the wafer boat is set to be equal to or more than a predetermined temperature difference by the inner cooling part.

### PRIOR ART DOCUMENT

### Patent Document

Patent Document 1: Japanese Laid-Open Patent Publication No. 2009-194099

### SUMMARY

According to one embodiment of the present disclosure, there is provided a film forming apparatus including: a processing container having an interior that is kept in a vacuum atmosphere; a stage provided within the processing container and configured to place a substrate thereon; a first film-forming gas supply part configured to supply a first film-forming gas into the processing container for forming an organic film on a member within the processing container; a second film-forming gas supply part configured to supply a second film-forming gas into the processing container for forming a film on the substrate; and a modifying gas supply part configured to supply a modifying gas for modifying the organic film and to suppress a film from being formed on a surface of the organic film by the second film-forming gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view of a film forming apparatus according to an embodiment of the present disclosure.

FIG. 2A is a flowchart illustrating a flow of a process performed in the film forming apparatus.

FIG. 2B is a flowchart illustrating a flow of a process performed in the film forming apparatus.

FIG. 3 is a vertical cross-sectional view of the film forming apparatus, which illustrates a process performed in the film forming apparatus.

FIGS. 4A to 4D are vertical cross-sectional views of a wafer, which illustrate a process performed in the film forming apparatus.

FIGS. 5A to 5D are vertical cross-sectional views of a wafer, which illustrate a process performed in the film forming apparatus.

FIG. 6 is a flowchart illustrating a flow of a process performed in the film forming apparatus.

FIG. 7 is an explanatory view illustrating a process performed in the film forming apparatus.

FIG. 8 is an explanatory view illustrating a process performed in the film forming apparatus.

FIG. 9 is an explanatory view illustrating a process performed in the film forming apparatus.

FIG. 10 is an explanatory view illustrating a process performed in the film forming apparatus.

FIG. 11 is a graph representing results of an evaluation test.

FIGS. 12A to 12E are schematic views illustrating results of an evaluation test.

FIG. 13 is a graph representing results of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

First, an outline of a film forming apparatus 1 according to an embodiment of the present disclosure will be described. The film forming apparatus 1 includes a processing container 11 whose interior is kept in a vacuum atmosphere. The film forming apparatus 1 supplies a film-forming gas to a wafer W in the vacuum atmosphere so as to form a polyurea film, which is composed of a polymer containing urea bonds, as an organic film, by vapor deposition polymerization. The film forming apparatus 1 also performs pre-coating. This pre-coating is a process of performing film formation on an internal member of the processing container 11 in order to adjust a film formation state of a wafer W before performing a film-formation process on the wafer W. In the film forming apparatus 1, similarly to the film formation on the wafer W, the film formation of a polyurea film is performed even in the pre-coating. Further, in the film forming apparatus 1, cleaning is also performed by supplying a cleaning gas into the processing container 11 so as to remove a pre-coated film (a film formed inside the processing container 11 by the pre-coating). The pre-coated film formed by the film forming apparatus 1 is composed of polyurea. That is, by the processing with this cleaning gas, a film formed on each member of the processing container 11 during the pre-coating and each time other than the pre-coating can be removed. As will be described later, the pre-coating is not always performed.

Meanwhile, in order to perform the above-mentioned vapor deposition polymerization, a temperature of the wafer W is adjusted by a stage 3 configured to heat the wafer W placed thereon such that the temperature becomes a film formation temperature at which a monomer contained in the film-forming gas can be adsorbed to the wafer W. Here, when the film formation process is performed on the wafer W, by setting a temperature of a region in which film formation is not desirable inside the processing container 11, to a temperature higher than the film formation temperature, that is, a temperature at which the adsorption of monomer hardly occurs, it is possible to suppress a deposition amount of the monomer. However, since the temperature of the wafer W is required to be adjusted by the stage 3 as described above, it is impossible to set the temperature of the stage 3 to such a relatively high temperature. As a result, as in the wafer W, a film may be formed outside the placement region of the wafer W on the surface of the stage 3 (that is, a peripheral edge portion of the stage 3).

Accordingly, when film formation is repeatedly performed on a plurality of wafers W, the polyurea film accumulates on the peripheral edge of the stage 3 and the thickness thereof increases. If such an accumulation progresses, particles are likely to be generated from the polyurea film thus accumulated. Further, since the film formation environment is changed between respective wafers W, there is a possibility that the uniform film formation process cannot be performed on each wafer W.

Therefore, in the film forming apparatus 1, after the pre-coating, a modifying gas is supplied into the processing container 11 to perform a process of modifying the surface of the pre-coated film. Such a modification hinders the formation of the polyurea film on the pre-coated film. That is, an increase in the film thickness of the polyurea film, which is the pre-coated film, is hindered at the peripheral edge of the stage 3. Specifically, the modification process is a fluorination process of exposing the surface of the pre-coated film to a gas containing fluorine as a constituent component and introducing fluorine into the surface. The surface of the film is made to be hydrophobic by the fluorination process, and thus the adsorption of the film-forming gas on the surface is hindered. The fluorination process and the cleaning process are, for example, plasma processes. The film forming apparatus 1 is configured to be able to perform the plasma processes. Further, the film forming apparatus 1 performs the fluorination process not only on the pre-coated film, but also on the polyurea film which may be formed on each part within the processing container 11 during the film formation on the wafers W, as will be described later. Thereby, the frequency of the cleaning process can be reduced.

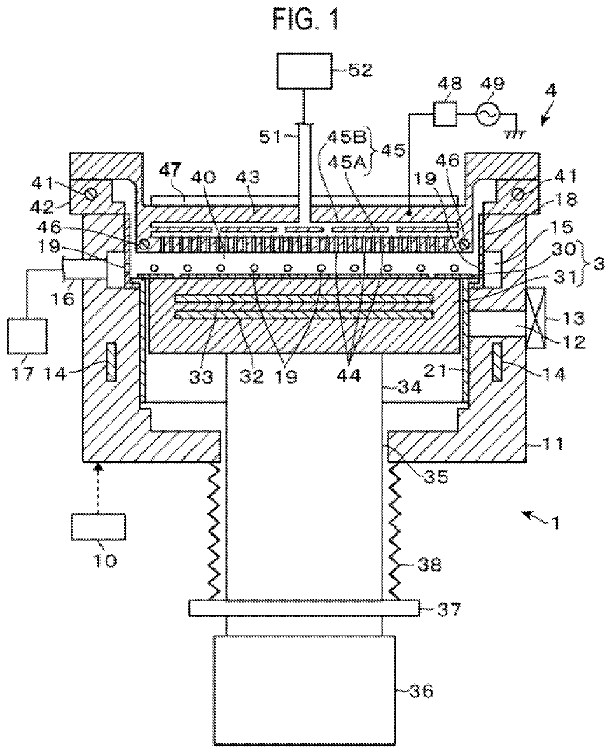

Hereinafter, a configuration of the film forming apparatus 1 will be described with reference to the vertical cross-sectional view of FIG. 1. As described above, the film forming apparatus 1 includes the processing container 11. The processing container 11 has a circular shape in a plan view. A transfer port 12 for the wafer W and a gate valve 13 for opening and closing the transfer port 12 are provided in the sidewall of the processing container 11. A heater 14 is embedded in the sidewall of the processing container 11. Further, in the sidewall of the processing container 11, an upper side protrudes towards the central portion of the processing container 11 more than a lower side so as to form a stepped portion. An annular recess is formed at the upper side of the stepped portion along the circumference of the processing container 11. The annular recess is configured as an exhaust path 15. An upstream end of an exhaust pipe 16 is connected to the exhaust path 15. A downstream end of the exhaust pipe 16 is connected to an exhaust mechanism 17 including, for example, a vacuum pump.

An upright cylindrical exhaust shield 18 is provided on the stepped portion of the sidewall of the processing container 11 so as to cover an inlet of the recess that constitutes the exhaust path 15. In the sidewall of the exhaust shield 18, a large number of exhaust ports 19 are opened at intervals along the circumference of the exhaust shield 18. As will be described later, the exhaust mechanism 17 is able to exhaust gas around the wafer W placed inward of the exhaust shield 18 through the exhaust ports 19. A lower end portion of the exhaust shield 18 protrudes inwards and is provided on the stepped portion of the sidewall of the processing container 11. An outer peripheral surface of the exhaust shield 18 is in contact with the sidewall of the processing container 11. Thus, the exhaust shield 18 is heated by heat radiated from the heater 14 that is provided in the sidewall of the processing container 11.

Further, an upright cylindrical lower shield 21 is provided inside the processing container 11. An upper end portion of the lower shield 21 protrudes outwards to form a flange. The flange is installed on the lower end portion of the exhaust shield 18. The lower shield 21 prevents the film-forming gas from flowing around and adhering to the lower end of the stage 3. In addition, a through-hole (not illustrated) is formed in a side portion of the lower shield 21 such that the wafer W can be delivered to a stage body 31 (described later) constituting the stage 3 via the transfer port 12.

A flat circular annular body 30 is provided on the upper end portion of the lower shield 21. The annular body 30 forms the stage 3 together with the stage body 31 located at a processing position described later, and constitutes a peripheral edge portion of the stage 3. Therefore, the fluorination process described above suppresses the film formation form being performed in a region including the annular body 30. An inner edge portion of the annular body 30 is located closer to the center side of the processing container 11 than an inner peripheral surface of the lower shield 21, and covers the peripheral edge of the stage body 31 located at the processing position described later. The inner edge portion of the annular body 30 is also close to the wafer W on the stage body 31. A position of the wafer W is regulated by being processed in the state of being surrounded by the annular body 30. The outer edge of the annular body 30 is provided away from the exhaust shield 18 such that that a temperature of the stage body 31 is not affected by the processing container 11.

Next, the stage body 31 will be described. The stage body 31 has a circular shape, and is surrounded by and provided in close to the inner peripheral wall of the lower shield 21. The wafer W is placed on the central portion of the front surface of the stage 3. A stage heater 32, which is a first heater for adjusting the temperature of the wafer W placed as described above, is embedded in the stage body 31. Further, the stage body 31 is provided with, for example, an electrode 33 for forming capacitively coupled plasma.

The stage body 31 is supported by a column 34. A lower end portion of the column 34 is connected to a lifting mechanism 36 via a through-hole 35 provided in the bottom of the processing container 11. By the lifting mechanism 36, the stage 3 is moved up and down between the processing position illustrated in FIG. 1 and a lower position below the processing position. The lower position is a position at which the wafer W is delivered between a transfer mechanism for wafer W (not illustrated) and the stage body 31. Pins for supporting the wafer W are provided inside the processing container 11 to perform the delivery. The pins is omitted in FIG. 1. Further, a flange 37 is formed on the column 34 outside the processing container 11. A bellows 38 connecting the flange 37 and an opening edge of the through-hole 35 ensures the airtightness inside the processing container 11.

A ceiling portion of the processing container 11 is constituted by a circular gas supply part 4. A peripheral edge portion of the gas supply part 4 is supported on the sidewall of the processing container 11 via a spacer 42 in which a heater 41 is embedded. The central portion of the gas supply part 4 is formed so as to be drawn downwards from the peripheral edge. A side peripheral surface of the gas supply part 4 is formed as a shower head 43 having a circular shape in a plan view which is close to the inner peripheral surface of the exhaust shield 18. The shower head 43 ejects a gas towards the stage 3 positioned below the shower head 43 in the form of a shower. Further, for example, the shower head 43 constitutes an electrode for forming the above-mentioned capacitively coupled plasma.

A large number of ejection ports 44 are provided in a lower surface of the shower head 43 in a distributed manner so that various gases can be supplied toward the wafer W in the form of a shower. Upper sides of the ejection ports 44 are connected to a gas diffusion space 45. For example, the diffusion space 45 is formed in upper and lower two stages. A lower diffusion space is indicated by reference numeral 45A, and an upper diffusion space is indicated by reference numeral 45B. In addition, in the shower head 43, a heater 46 is embedded outside the region where the ejection ports 44 are formed. A heater 47 is provided above the shower head 43 so as to be stacked on the shower head 43. A high-frequency power supply 49 for applying a high-frequency voltage to the shower head 43 is connected to the shower head 43 via a matcher 48. The heaters 46 and 47 heat the shower head 43 together with the heater 41 of the spacer 42. These heaters 41, 46, and 47 constitute a second heater together with the heater 14 for heating the sidewall of the processing container 11 and the exhaust shield 18 described above.

A downstream end of a gas supply pipe 51 that supplies a gas to the diffusion space 45 is connected to the upper portion of the shower head 43. An upstream end of the gas supply pipe 51 is connected to a gas supply mechanism 52 including, for example, a valve, a mass flow controller, and a gas source. The gas supply mechanism 52 is configured to be capable of supplying each of an amine gas, an isocyanate gas, a nitrogen trifluoride (NF₃) gas which is a gas for the fluorination process, an active oxygen gas which is a cleaning gas, and a nitrogen (N₂) gas which is a purge gas, to the shower head 43. The active oxygen gas includes, for example, an ozone (O₃) gas. In addition, the gas supply mechanism 52 also supplies an argon (Ar) gas that is a cleaning gas, other than the active oxygen gas, to the shower head 43.

The amine gas is, for example, a gas containing 1,3-bis(aminomethyl)cyclohexane (H6XDA) which is a diamine. The above-mentioned isocyanate gas is, for example, a gas containing diisocyanate 1,3-bis(isocyanatomethyl)cyclohexane (H6XDI). The amine gas and the isocyanate gas are first film-forming gases for performing the pre-coating and second film-forming gases for performing the film formation on the wafer W. That is, in this embodiment, the first film-forming gases and the second film-forming gases are gases containing the same material. The shower head 43 constitutes a first film-forming gas supply part, a second film-forming gas supply part, a modifying gas supply part, and a cleaning gas supply part.

When the stage body 31 is located at the processing position, a space surrounded by the stage 3, the exhaust shield 18, and the shower head 43, which are members inside the processing container 11, is referred to as a processing space 40. The shower head 43 and the exhaust shield 18 constitute the inner wall of the processing container 11 when viewed from the wafer W. A temperature sensor is embedded in the shower head 43 to perform a feedback control such that the temperature of the bottom surface of the shower head 43 reaches a set temperature. Herein the temperature sensor is omitted.

The film forming apparatus 1 includes a controller 10. The controller 10 is configured with a computer, and includes a program, a memory, and a CPU. The program incorporates a group of steps such that the film forming apparatus 1 is capable of performing a series of operations described later. The controller 10 outputs a control signal to each part of the film forming apparatus 1 by the program so as to control the operation of each part. Specifically, operations, such as the adjustment of the supply and flow rate of each gas by the gas supply mechanism 52, the adjustment of the output of each heater, and the adjustment of the exhaust amount by the exhaust port 19, are controlled by the control signal. The adjustment of the exhaust amount may correspond to adjusting an internal pressure of the processing container 11. The adjustment of the output of each heater may correspond to adjusting the temperature of each part of the processing container 11. The above-mentioned program is stored in a storage medium such as a compact disc, a hard disc, or a DVD, and is installed in the controller 10.

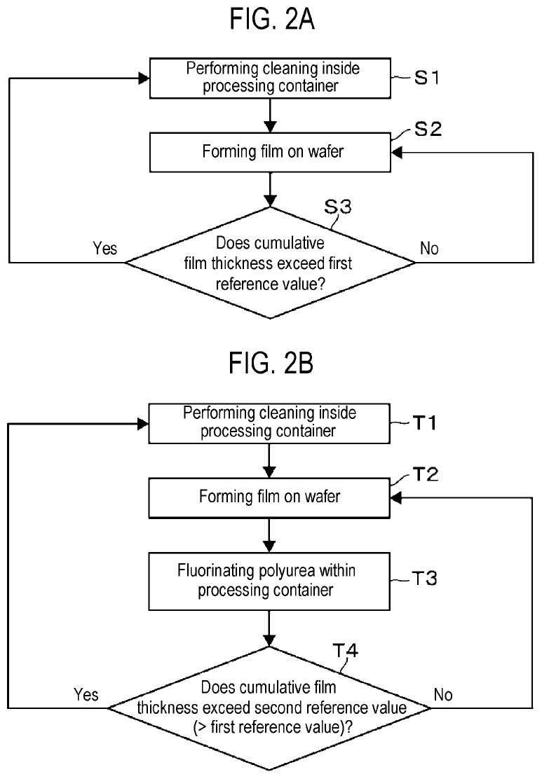

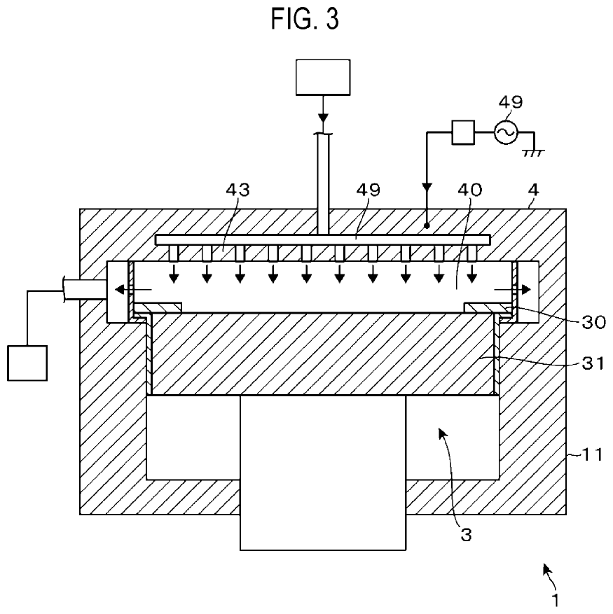

Next, with reference to FIGS. 2A and 2B, a cleaning cycle in Comparative example (a cycle including film formation on the wafer W and cleaning) and a cleaning cycle in Example will be described. FIG. 2A illustrates a flow of the cleaning cycle in Comparative example, and FIG. 2B illustrates a flow of the cleaning cycle in Example. In the description of these cleaning cycles, FIG. 3 illustrating the inside of the processing container 11 is also referred to. In FIG. 3 and FIGS. 7 to 10 described later, for the sake of clearly illustrating the state of film formation while avoiding complexity of illustration, the configuration of each part of the film forming apparatus 1 is simplified compared with FIG. 1. In Comparative example and Example, a plurality of wafers W are sequentially transferred to the film forming apparatus 1 where the plurality of wafers W are processed, and polyurea films having the same film thickness are assumed to be formed on respective wafers W.

Now, the cleaning cycle in Comparative example will be described. First, in the state in which no wafer W is loaded into the processing container 11, the stage body 31 is located at the processing position, and the stage 3 is formed by the stage body 31 and the annular body 30. Then, in the state in which the inside of the processing container 11 is evacuated to become a vacuum atmosphere having a preset pressure, an active oxygen gas is ejected from the shower head 43 into the processing space 40. In addition, the high-frequency power supply 49 is turned on, and the active oxygen gas is plasmarized. The polyurea film that has been formed on each part of the processing container 11 by the film formation process performed thus far is ashed and removed by the plasma (step S1, FIG. 3). In step S1, a surface temperature of the stage 3 is, for example, higher than a temperature in each step S to be described later. Specifically, the surface temperature of the stage 3 is, for example, 150 degrees C. to 250 degrees C.

After the ashing, the high-frequency power supply 49 is turned off and the supply of the active oxygen gas from the shower head 43 is stopped. Thereafter, the output of each of the heaters 14, 32, 41, and 46 is adjusted such that each of surface temperatures of the shower head 43, the exhaust shield 18, and the stage 3 facing the processing space 40 becomes a film formation temperature at which the amine gas and the isocyanate gas as the film-forming gases can be adsorbed, for example, 80 degrees C. Then, the wafer W is loaded into the processing container 11, and a gas supply cycle in which the amine gas, the N₂ gas, the isocyanate gas, and the N₂ gas are sequentially ejected from the shower head 43 is repeated. On the bottom surface of the shower head 43, the inner peripheral surface of the exhaust shield 18, and the surface of the wafer W placed on the stage 3, the temperature of each of these members is relatively low. Thus, adsorption of the amine gas and the isocyanate gas supplied in the gas supply cycle proceeds. Then, polyurea is produced by polymerization of the adsorbed amine and the adsorbed isocyanate (step S2).

The above-mentioned gas supply cycle is repeated such that a polyurea film having a predetermined film thickness, for example, 10 nm, is formed on the wafer W. After forming the polyurea film on one wafer W in this manner, a subsequent wafer W is transferred into the processing container 11 and is sequentially processed. Each time one wafer W is processed, it is determined whether or not a cumulative value of the film thickness after performing the most recent cleaning in step S1 (thickness of film formed on one wafer W×the number of processed wafers W) exceeds a first reference value, for example, 10 μm (step S3). When it is determined that cumulative value exceeds the first reference value, the cleaning in step S1 is performed as described above, and when it is determined that cumulative value does not exceed the first reference value, step S2, that is, the film formation process on the subsequent wafer W is performed.

Next, the cleaning cycle in Example will be described. First, in the state in which no wafer W is loaded into the processing container 11, the stage body 31 is located at the processing position. The stage 3 is formed by the stage body 31 and the annular body 30. Then, in the state in which the inside of the processing container 11 is evacuated to become a vacuum atmosphere having a preset pressure, the Ar gas is ejected from the shower head 43 into the processing space 40. In addition, the high-frequency power supply 49 is turned on, and the Ar gas is plasmarized. The polyurea film that has been formed in each part of the processing container 11 by the film formation process performed thus far is ashed and removed by the plasma (step T1, FIG. 3). In this step T1, a surface temperature of the stage 3 is, for example, higher than a temperature in each subsequent step T. Specifically, the surface temperature of the stage 3 is, for example, 150 degrees C. to 250 degrees C.

After the ashing, the high-frequency power supply 49 is turned off, and the supply of the Ar gas from the shower head 43 is stopped. Thereafter, the output of the heater 32 is adjusted such that each of surface temperatures of the shower head 43, the exhaust shield 18, and the stage 3 facing the processing space 40 becomes a film formation temperature at which the amine gas and the isocyanate gas as the film-forming gases can be adsorbed, for example, 80 degrees C. Then, the wafer W is loaded into the processing container 11, and a gas supply cycle in which the amine gas, the N₂ gas, the isocyanate gas, and the N₂ gas are sequentially ejected from the shower head 43 is repeated. On the bottom surface of the shower head 43, the inner peripheral surface of the exhaust shield 18, and the surface of the wafer W placed on the stage 3, the temperature of each of these members is relatively low. Thus, adsorption of the amine gas and the isocyanate gas supplied in the gas supply cycle proceeds. Then, a polyurea film is produced by polymerization of the adsorbed amine and the adsorbed isocyanate (step T2).

When the polyurea film formed on the wafer W has a preset film thickness, for example, 10 nm, the gas supply cycle is stopped. After the processed wafer W is unloaded from the processing container 11, and before a subsequent wafer W is loaded into the processing container 11, a NF₃ gas, which is a modifying gas, is ejected from the shower head 43, and the high-frequency power supply 49 is turned on so that the NF₃ gas is plasmarized. A surface layer of the polyurea film formed on each part within the processing container 11 is subjected to the fluorination process by the plasma of the NF₃ gas, so that a high hydrophobic layer 62 (not shown in FIGS. 1 to 3) is formed (step T3).

Thereafter, the high-frequency power supply 49 is turned off and the supply of the NF₃ gas to the processing space 40 is stopped. The film formation process on the wafer W in step T2 may be a process for forming a film on one sheet of wafer W or a process for forming films on a predetermined plural sheets of wafers W. As will be described in the following evaluation tests, when the film-forming gas is continuously supplied to the hydrophobic layer 62 after the hydrophobic layer 62 is formed, the adsorption of the film-forming gas to the hydrophobic layer 62 is hindered for a while. However, when the supply of the film-forming gas is further continued, the film-forming gas is adsorbed, a thin layer of the polyurea film is eventually formed so as to cover the hydrophobic layer 62, and this thin layer grows. That is, the effect of the hydrophobic layer 62 disappears at a certain point in time, and the film thickness of the polyurea film may increase. Therefore, the fluorination process is performed again before the effect of the hydrophobic layer 62 disappears.

As described above, while the polyurea film is formed on one wafer W and the subsequent fluorination process is performed, after the most recent step T1 (cleaning) is performed, the controller 10 determines whether the cumulative value of the film thickness exceeds a preset second reference value (step T4). When it is determined that the cumulative value of the film thickness does not exceed the second reference value, the surface temperature of the stage 3 is maintained at, for example, 80 degrees C. even after the supply of the NF₃ gas is stopped as described above. Then, the subsequent wafer W is transferred into the processing container 11, and each step from step T2 is performed.

In step T2, film formation is performed on the wafer W, and on the stage 3, the peripheral edge including the annular body 30 outside the wafer W is also exposed to the film-forming gas (the amine gas and the isocyanate gas). However, since the surface layer of the polyurea film formed on the peripheral edge is the hydrophobic layer 62, the adsorption of the film-forming gas is suppressed. That is, in the peripheral edge of the stage 3, the formation of the polyurea film and the increase in the film thickness are suppressed. The adsorption of the film-forming gas is also suppressed on the bottom surface of the shower head 43 and the inner peripheral surface of the exhaust shield 18 by the formation of the hydrophobic layer 62, as on the annular body 30.

When it is determined in step T4 that the cumulative value of the film thickness exceeds the second reference value, the cleaning process in step T1 is performed again. That is, the controller 10 determines the timing of performing cleaning based on the determination result of step T4 in repeating the film formation process of step T2. For example, in accordance with such a determination, the controller 10 also outputs a control signal to the transfer mechanism that transfers the wafer W to the film forming apparatus 1 so as to control the timing of transferring the subsequent wafer W into the processing container 11.

The second reference value used for the determination in step T4 is a value larger than the first reference value used for the determination in step S3 of Comparative example. Accordingly, for example, in the cycle of Comparative example described above, assuming that the number of processed wafers W between cleanings is 1,000, the number of processed wafers W is more than 1,000 in the cycle of Example. By allowing the surface layer of the polyurea film to be subjected to the fluorination process as described above, the formation of the polyurea film on the surface layer is suppressed. That is, while the film formation is performed on the wafer W, the increase in the thickness of the polyurea film in each of the other members within the processing container 11 is suppressed.

The process flow proceeds as described above, and the processes of steps T2 and T3 are repeatedly performed to process the plurality of wafers W. Then, the repetition is stopped at, for example, an arbitrary timing preset by the user. As a specific example, when the number of times of performing each of steps T2 and T3 exceeds a reference number of times, the above-described steps T2 and T3 are terminated, and the operations subsequent to step T1 described above are performed. The polyurea film formed on each wafer W are used as, for example, a sacrificial film during an etching process. After the etching process is completed, the polyurea film is removed by heating-based depolymerization.

According to the film forming apparatus 1 described above, the fluorination process using the plasma of NF₃ gas is performed on the polyurea film formed inside the processing container 11 while the polyurea film is formed on the plurality of wafers W, thus forming the hydrophobic layer 62. Then, the film formation process on the wafer W and the above-mentioned fluorination process are repeatedly performed after the cleaning is performed and before the subsequent cleaning is performed. This suppresses an increase in the thickness of the polyurea film on the members other than the wafer W inside the processing container 11 during the film formation process on the wafer W, which makes it is possible to increase the number of wafers W to be processed after the current cleaning is completed and before the subsequent cleaning is performed. That is, it is possible to reduce the number of times of performing cleaning per the number of processed wafers W and to enhance the productivity of the film forming apparatus 1 per unit time.

Further, according to the film forming apparatus 1 described above, film formation is limitedly performed on the wafers W by the supply of the film-forming gas and the supply of the NF₃ gas, while the film formation on each part within the processing container 11 is suppressed. Accordingly, it is possible to eliminate a need to form the flow path of coolant for forming a temperature difference in each part of the film forming apparatus 1 for the purpose of forming a film on the wafer W in a limited manner. Accordingly, there is an advantage that the apparatus configuration can be simplified. However, the formation of such a coolant flow path is not prohibited. As described above, in Comparative example, the cleaning is performed by the plasma of the active oxygen gas, and in Example, the cleaning is performed by the plasma of the Ar gas. However, in Example, the cleaning may be performed by the plasma of the active oxygen gas.

Although the film forming apparatus 1 has been described as having the configuration in which high-frequency waves are applied to the shower head 43 to form plasma inside the processing container 11, the film forming apparatus 1 is not limited to such a configuration example. For example, the film forming apparatus 1 may have a configuration in which the gas supply mechanism 52 includes a remote plasma source, and the plasma of Ar gas and the plasma of NF₃ gas are supplied to the processing space 40 via the shower head 43. Further, in order to increase the reactivity, the process has been described to be performed by plasmarizing the NF₃ gas. However, the present disclosure is not limited to such a plasma-based process.

In addition, the gas for forming the hydrophobic layer 62 is not limited to the NF₃ gas, but may be, for example, a gas including a fluorine-containing compound, such as fluorine trichloride (ClF₃), trifluoromethane (CHF₃), ethane hexafluoride (C₂F₆) or the like, other than the NF₃ gas. That is, any compound may be used as long as it can provide hydrophobic property by fluorinating the surface of an organic film. The fluorine-containing compound described above may include fluorine itself, that is, F₂, and a process may be performed using plasma of the F₂ gas, or non-plasmarized F₂ gas. Unless the surface of the wafer W is made of a material that inhibits subsequent film formation by the fluorination process, the fluorination process may be performed in the state in which the wafer W is placed on the stage 3.

The gas supply part is not limited to being configured with the shower head. For example, the gas supply part may have a configuration in which each gas is supplied to the processing space 40 by a nozzle. Alternatively, the gas supply part may have a configuration in which each gas is supplied to the processing space 40 from the gas supply part that forms the ceiling portion of the processing container 11 and has gas ejection ports formed to be opened in a concentric relationship with each other. The gas supply part may have a configuration in which the first film-forming gas, the second film-forming gas, and the modifying gas are supplied into the processing container 11 from different ejection ports, respectively. That is, a first film-forming gas supply part, a second film-forming gas supply part, and a modifying gas supply part may be separated from each other. In the above example, the amine gas and the isocyanate gas are supplied to the processing space 40 at different timings so as to perform the film formation. However, these film-forming gases may be simultaneously supplied to the processing space 40 so as to perform the film formation.

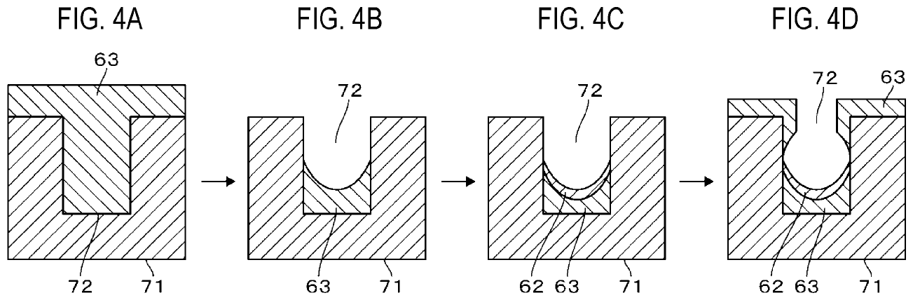

With the film forming apparatus 1, it is possible to control a formation position of film on the wafer W. An example of a first film formation process will be described with reference to FIGS. 4A to 4D illustrating vertical cross-sectional views of the wafer W. An inorganic film 71 is formed on a surface of the wafer W. The inorganic film 71 may be made of a material that is not hydrophobized or hardly hydrophobized even when a gas for performing the above-mentioned fluorination process is supplied. Specifically, the inorganic film 71 may be made of, for example, a semiconductor, such as S1, or a metal, such as Ti or Al.

A recess 72 is formed in a surface of the inorganic film 71. Film formation is performed by the film forming apparatus 1 such that a polyurea film 63 is embedded in the recess 72 (FIG. 4A). Thereafter, the wafer W is transferred to an etching apparatus provided outside the film forming apparatus 1. In the etching apparatus, etching is performed such that the polyurea film 63 remains in a lower portion of the recess 72 and is removed outside the recess 72 other than the lower portion to expose the inorganic film 71 (FIG. 4B). Subsequently, the wafer W is transferred to the film forming apparatus 1 again, and the fluorination process described as step T3 in the flow of FIG. 2B is performed to modify the surface layer of the polyurea film 63 so as to form a hydrophobic layer 62 (FIG. 4C). Then, the film formation process described as step T2 is performed. Since the hydrophobic layer 62 is formed, the polyurea film 63 is not formed on the polyurea film 63 in the recess 72, but is formed from the upper portion of the sidewall of the recess 72 to the outer region of the recess 72 (FIG. 4D).

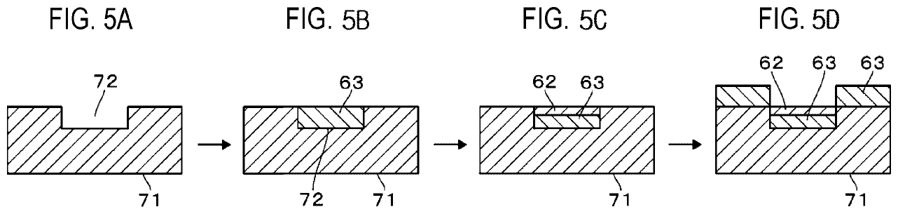

Next, with reference to FIGS. 5A to 5D, an example of a second film formation process will be described with a focus on the differences from the first film formation process. Even in the second film formation process, an inorganic film 71 having a recess 72 is formed on the surface of the wafer W (FIG. 5A). However, the recess 72 is formed to have a relatively shallow depth. By the film forming apparatus 1, a polyurea film 63 is formed to be embedded in the recess 72, and subsequently, by an etching apparatus, etching is performed such that the polyurea film 63 remains in the recess 72 and the inorganic film 71 is exposed at a region other than the recess 72 (FIG. 5B). Then, the fluorination process of step T3 is performed to form a hydrophobic layer 62 on the surface of the polyurea film 63 (FIG. 5C). Then, by performing the film formation process of step T2, the polyurea film 63 is formed outside the recess 72 in a limitative manner (FIG. 5D).

As illustrated in the first film formation process and the second film formation process, the polyurea film 63 formed on the wafer W is shaped by the etching, and subsequently, the fluorination process is performed to form a second round of polyurea film 63 on the wafer W. Thus, by the second round of film formation, it is possible to form the polyurea film 63 on a desired position on the wafer W in a limitative manner. The film formed on the wafer W in a limitative manner is not limited to the polyurea film, but various organic films (to be described later) other than the polyurea film 63 may be formed instead of the polyurea film 63.

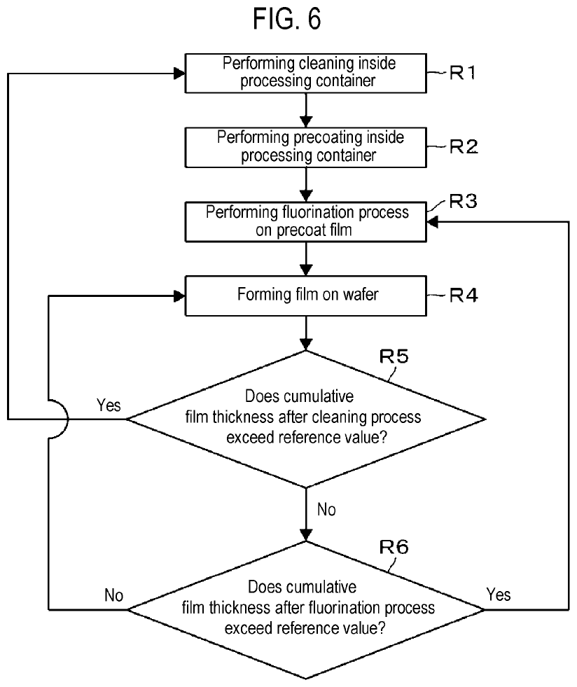

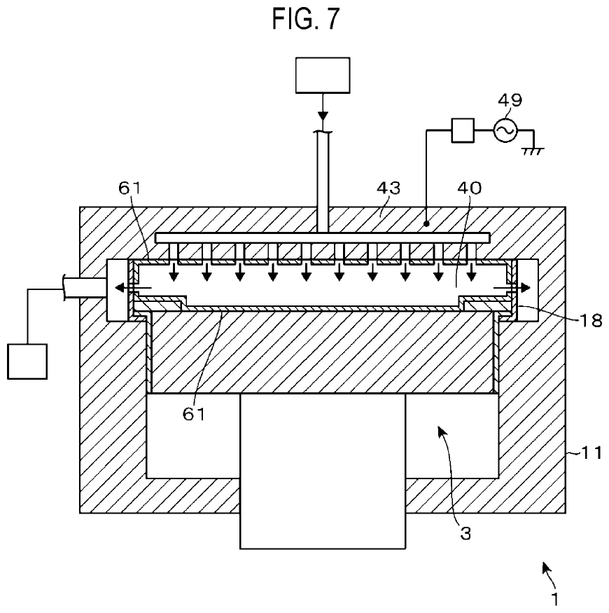

Next, an example of a wafer process including the pre-coating will be described with reference to a flowchart of FIG. 6, FIG. 3 described above, and FIGS. 7 to 10 each illustrating the inner state of the processing container 11 as in FIG. 3. In this exemplary process, polyurea films are continuously formed on a plurality of wafers W so as to have the same film thickness.

First, in the state in which no wafer W is loaded into the processing container 11, the stage body 31 is located at the processing position so that the stage 3 is constituted by the stage body 31 and the annular body 30. Then, in the state in which the inside of the processing container 11 is evacuated to become a vacuum atmosphere having a preset pressure, the Ar gas is ejected from the shower head 43 into the processing space 40. In addition, the high-frequency power supply 49 is turned on, and the Ar gas is plasmarized. By plasma of the Ar gas, a pre-coated film that has been formed by the film formation process performed thus far is ashed and removed (step R1, FIG. 3). In step R1, a surface temperature of the stage 3 is higher than, for example, a temperature in each subsequent step R. Specifically, the surface temperature of the stage 3 is, for example, 150 degrees C. to 250 degrees C.

After the ashing, the high-frequency power supply 49 is turned off, and the supply of the Ar gas from the shower head 43 is stopped. Thereafter, the output of each of the heaters 14, 32, 41, and 46 is adjusted such that each of surface temperatures of the shower head 43, the exhaust shield 18, and the stage 3 facing the processing space 40 becomes a film formation temperature at which the amine gas and the isocyanate gas as the film-forming gases can be adsorbed, for example, 80 degrees C. Then, a gas supply cycle in which the amine gas, the N₂ gas, the isocyanate gas, and the N₂ gas are sequentially ejected from the shower head 43 is repeated. On the bottom surface of the shower head 43, the inner peripheral surface of the exhaust shield 18, and the surface of the stage 3, since the temperature of each of these members is relatively low, adsorption of the amine gas and the isocyanate gas supplied in the gas supply cycle proceeds. Then, polyurea is produced by polymerization of the adsorbed amine and the adsorbed isocyanate. That is, a pre-coated film 61 is formed to surround the processing space 40, and the film thickness thereof increases (step R2: pre-coating step, FIG. 7).

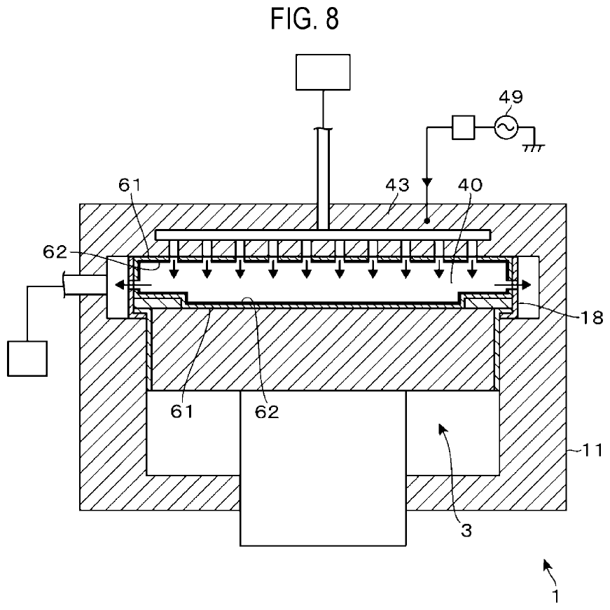

When the pre-coated film 61 has a preset film thickness, the above-described gas supply cycle is stopped, the NF₃ gas, which is a modifying gas, is ejected from the shower head 43, the high-frequency power supply 49 is turned on so that the NF₃ gas is plasmarized. The surface layer of the pre-coated film 61 is fluorinated by plasma of the NF₃ gas, and is turned into the hydrophobic layer 62 having high hydrophobicity (step R3: modifying step, FIG. 8).

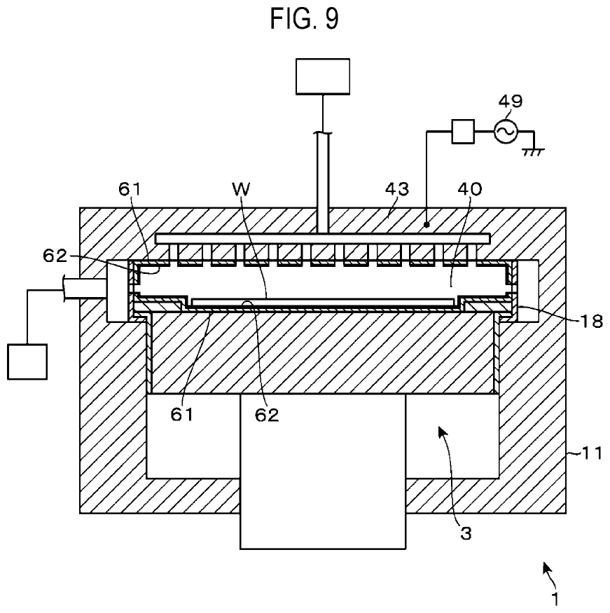

Thereafter, the high-frequency power supply 49 is turned off, and the supply of the NF₃ gas to the processing space 40 is stopped. The temperature of the surface of the stage 3 is maintained at, for example, 80 degrees C. Thereafter, the wafer W is loaded into the processing container 11 and is placed on the stage 3 (FIG. 9). Then, when the wafer W is heated to 80 degrees C., which is the same temperature as that of the stage 3, the gas supply cycle in which the amine gas, the N₂ gas, the isocyanate gas, and the N₂ gas are sequentially ejected from the shower head 43 is repeated as in step R2. Since the temperature of the surface of the wafer W exposed to the amine gas and the isocyanate gas is relatively low, the adsorption of the amine gas and the isocyanate gas proceeds, and the polyurea film 63 is formed by the polymerization of the adsorbed amine and the adsorbed isocyanate so that the film thickness of the polyurea film 63 is increased.

Meanwhile, on the stage 3, the peripheral edge portion including the annular body 30 outward of the wafer W is also exposed to the film-forming gas (the amine gas and the isocyanate gas). However, since the surface layer of the pre-coated film 61 formed on the peripheral edge portion is the hydrophobic layer 62, the adsorption of the film-forming gas onto the peripheral edge portion is suppressed. That is, in the peripheral edge portion of the stage 3, the additional formation of the polyurea film on the pre-coated film 61 as a polyurea film is suppressed.

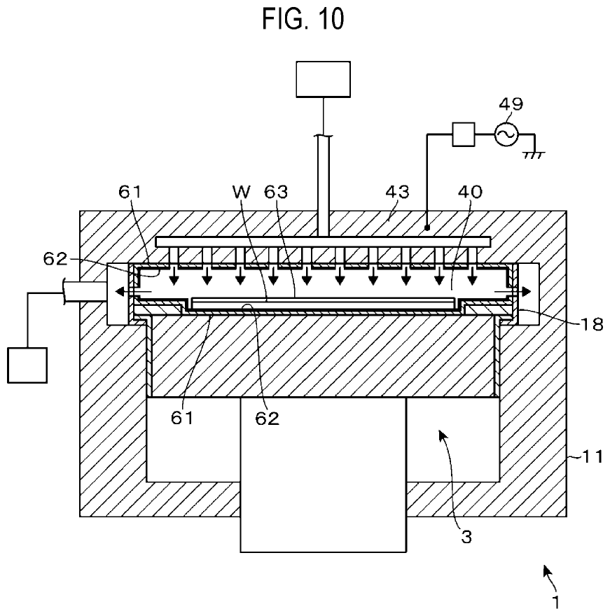

Since the hydrophobic layer 62 is formed on the bottom surface of the shower head 43 and the inner peripheral surface of the exhaust shield 18, as on the peripheral edge portion of the stage 3, the adsorption of the film-forming gas onto the bottom surface of the shower head 43 and the inner peripheral surface of the exhaust shield 18 is also suppressed. Thus, in the processing space 40, the polyurea film 63 is selectively formed on the surface of the wafer W on which the hydrophobic layer 62 is not formed so that the film thickness thereof is increased (step R4: substrate film-forming step, FIG. 10).

When the thickness of the polyurea film 63 on the wafer W reaches the set value, the gas supply cycle is stopped, and the wafer W is unloaded from the processing container 11. Meanwhile, the controller 10 determines whether or not the cumulative value of the film thickness exceeds the second reference value described in the flow of FIG. 2B after performing the most recent cleaning in step R1 (step R5). When it is determined that the cumulative value of the film thickness exceeds the second reference value, the cleaning in step R1 is performed. When it is determined that the cumulative value of the film thickness does not exceed the second reference value, the most recent step R3 (the fluorination process on the pre-coated film) is performed, and then it is determined whether the cumulative value of the film thickness formed on the wafer W exceeds a preset third reference value (step R6). In this embodiment, since the polyurea film is formed to have the same film thickness on respective wafers W, the cumulative value of the film thickness is equal to the number of times of film formation on the wafer W performed in step R6×the set film thickness of the wafer W. The third reference value related to the cumulative value of the film thickness is, for example, 50 nm.

Then, when it is determined in step R6 that the cumulative value of the film thickness does not exceed the third reference value, a subsequent wafer W is loaded into the processing container 11, and the film formation process of step R4 is performed on the respective wafer W. Meanwhile, when it is determined in step R6 that the cumulative value of the film thickness exceeds the third reference value, the fluorination process of step R3 is performed again. That is, the controller 10 determines whether to repeat the fluorination process in the processing container 11 based on the determination result in step R6 in repeating the film formation process of step R4. For example, in accordance with such a determination, the controller 10 also outputs a control signal to the transfer mechanism that transfers the wafer W to the film forming apparatus 1 so as to control the timing of transferring the subsequent wafer W into the processing container 11.

The reason why the aforementioned determination in step R6 is performed is that, as described above, when the film-forming gas is continuously supplied to the hydrophobic layer 62 after the hydrophobic layer 62 is formed, the effect of the hydrophobic layer 62 disappears at a certain point of time and the thickness of the polyurea film increases. That is, the fluorination process is performed again before the effect of the hydrophobic layer 62 disappears, and the determination in step R6 is performed to newly form the hydrophobic layer 62.

The second reference value related to the cumulative value of the film thickness, which is used in step R5 in the flow of FIG. 6, is set, for example, to be larger than 10 μm, as in step 2B in the flow of FIG. 2B. As a result, the cleaning is performed, for example, every 1,000 to 10,000 sheets of wafers W. As illustrated in the pre-coating flow and the cleaning cycle in FIG. 2B, the film forming apparatus 1 sequentially and repeatedly performs the supply of the film-forming gas for forming a film on the wafer W and the supply of the modifying gas.

By controlling the temperature of each heater during the pre-coating in the film forming apparatus 1, the film-forming gas is supplied to the processing space 40 in the state where the temperature of the exhaust shield 18 and the temperature of the shower head 43 are higher than the temperature of the stage 3. As a result, the pre-coated film 61 is formed on the surface of the stage 3, whereas no pre-coated film 61 is formed on the inner peripheral surface of the exhaust shield 18 and the bottom surface of the shower head 43. Thereafter, the surface layer of the pre-coated film 61 is turned into the hydrophobic layer 62 by the fluorination process, and subsequently, the film formation process on the wafer W is performed. At this time, the temperature of each heater is controlled such that no polyurea film 63 is formed on the surfaces of the shower head 43 and the exhaust shield 18. That is, the pre-coated film 61 and the hydrophobic layer 62 may be formed only on arbitrary positions in the processing container 11 in a limitative manner so as to perform the film formation process. The pre-coated film 61 and the hydrophobic layer 62 are not limited to being formed on the entire surface of each member within the processing container 11.

Meanwhile, it is preferable to form the pre-coated film 61 on the entire wall surface forming the processing space 40 in order to make the film-forming environment uniform between wafers W. Thus, it is possible to perform the processes as described with reference to FIG. 3 and FIGS. 7 to 10. When the pre-coated film 61 and the hydrophobic layer 62 are formed only in a portion of the processing space 40 as described above, the stage 3 cannot be heated to a high temperature for film formation on the wafers W as described above. Thus, it is preferable to form the pre-coated film 61 and the hydrophobic layer 62 at least on the stage 3.

In the above-described embodiment, the example in which polyurea is used as the material of the organic film and the pre-coated film formed on the wafer W has been described, but other organic materials may be used. For example, polyimide that is a material of an insulating film may be used. In addition to the polyimide, polyurethane, acrylic resin, polyolefin, polycarbonate, polyamide, phenol resin, or the like may be used. Further, film formation may be performed through vapor deposition polymerization of a compound of these materials. Further, the organic film is not limited to being composed of a polymer material, but may be composed of a low molecular material. Further, the organic film may be a film composed of an organic material having hydrophobicity by the fluorination process. While H6XDA and H6XDI are used as examples of the material for forming the polyurea film, the present disclosure is not limited to these materials. For example, other known materials may be used to form the polyurea film.

The film formed on the wafer W may be any film formed by a film-forming gas that inhibits formation of a film on a fluorinated pre-coated film. Therefore, the pre-coated film and the film formed on the wafer W may not necessarily the same. The film formed on the wafer W is not limited to an organic film, but may be, for example, a semiconductor, such as silicon (Si) or an inorganic film made of a metal, such as titanium (Ti) or aluminum (Al). However, from the viewpoint of preventing foreign matters from entering the film formed on the wafer W, the pre-coated film and the film formed on the wafer W are preferably made of the same material. The technology disclosed herein is not limited to the embodiments described above, and various modifications, omissions, and substitutions can be made within the scope of the gist of the present disclosure.

### (Evaluation Tests)

Next, evaluation tests performed in relation to the embodiment described above will be described.

### (Evaluation Test 1)

In Evaluation Test 1, after the polyurea film is formed on the wafer W, the plasma of NF₃ gas described in step T3 was supplied to perform the fluorination process. The temperature of the wafer W in the fluorination process was changed within the range of 90 degrees C. to 120 degrees C. for each wafer W. Water was dropped on the surface of the polyurea film for each wafer W after the fluorination process, and the contact angles of water droplets were measured.

More specifically, the processing conditions in the above-described fluorination process were set such that the internal pressure of the processing container 11 was 1 Torr (133.3 Pa), and the flow rate of the NF₃ gas supplied into the processing container 11 was 300 sccm. Further, the Ar gas was supplied into the processing container at 1,000 sccm together with the NF₃ gas, and the supply time of the NF₃ gas and the Ar gas was 180 seconds. During the supply of each of these gases, the temperature of the shower head 43 was set to 180 degrees C., and the temperature of the sidewall of the processing container 11 was set to 120 degrees C. The distance between the shower head 43 and the wafer W was 150 mm. In Comparative test, the contact angles of water droplets were measured for the wafer W that was not subjected to the fluorination process after the polyurea film was formed, as in the case of the wafer W that was subjected to the fluorination process.

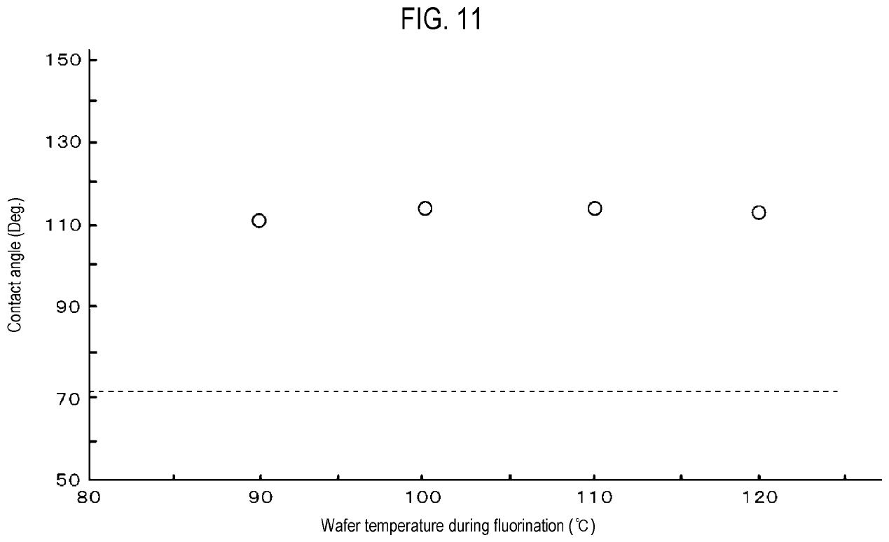

A graph of FIG. 11 shows the contact angle for each processing temperature for the wafer W that was subjected to the fluorination process. As is apparent from the graph, the contact angles of the water droplets obtained from the wafer W, which was fluorinated at 90 degrees C., 100 degrees C., 110 degrees C., and 120 degrees C., were 112.0 degrees, 114.4 degrees, 114.9 degrees, and 113.2 degrees, respectively. Further, the contact angle of the water droplet obtained from the wafer W which is not subjected to the fluorination process in Comparative test was 72.5 degrees, which is indicated by the dotted line in the graph. Accordingly, it was confirmed that in the range of 90 degrees C. to 110 degrees C., the surface of the polyurea film was hydrophobized by the fluorination process regardless of the processing temperature during the fluorination process.

### (Evaluation Test 2)

In Evaluation Test 2, a polyurea film having a thickness of 200 nm was formed on each of a plurality of wafers W. Subsequently, each wafer W was subjected to the above-mentioned fluorination process using the plasma of NF₃ gas, and then, the second round of film formation process was performed to form the polyurea film. The times of the second round of film formation process of the polyurea film were changed for respective wafers W, and were set to 0.5 minutes, 2 minutes, 6 minutes, 10 minutes, and 20 minutes, respectively. After the second round of film formation process, each wafer W was imaged with an electron microscope (SEM). The thicknesses of the polyurea film 63 formed by the first and second rounds of film formation processes were measured. Meanwhile, in Comparative Test 2, the same test as Evaluation Test 2 was performed except that the fluorination process was not performed.

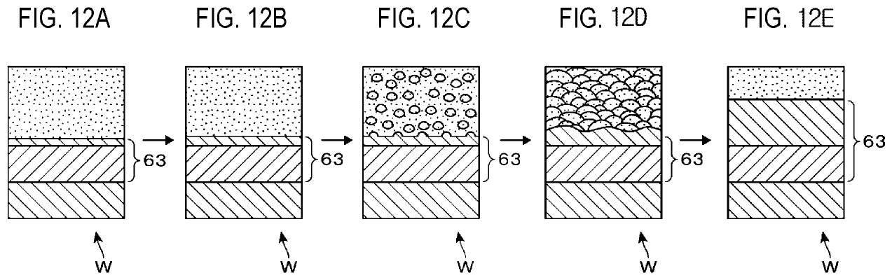

In Comparative Test 2, the longer the time of the second round of film formation process, the larger the thickness of the polyurea film 63. The results of Evaluation Test 2 will be described with reference to FIGS. 12A to 12E. FIGS. 12A to 12E schematically show images of panoramic cross sections obtained from the wafer W in Evaluation Test 2, which illustrate vertical cross sections and the surfaces of the wafers W, respectively. FIGS. 12A to 12E show the wafers W when the times of the second round of film formation process were 0.5 minutes, 2 minutes, 6 minutes, 10 minutes, and 20 minutes, respectively. The surface of each wafer W in the drawings is expressed with a large number of dots in order to facilitate discrimination.

On the wafers W, on which the times of the second round of film formation process were 0.5 minutes and 2 minutes in Evaluation Test 2, the thicknesses of the polyurea films 63 were substantially the same. That is, no growth of the polyurea films 63 was observed during these film formation times. On the wafer W, on which the time of the second round of film formation process was 6 minutes, a partial growth of the polyurea film 63 was observed. More specifically, extremely small granular films were formed dispersedly on the surface (hydrophobic surface) of the polyurea film formed in the first round of film formation process. However, since the grains are small, the film thickness is substantially the same as the film thicknesses of the wafers W, on which the times of the second round of film formation process were 0.5 minutes and 2 minutes. On the wafer W, on which the time of the second of film formation process was 10 minutes, the above-mentioned granular films were enlarged and covered the surface of the polyurea film 63 formed in the first round of film formation process. Due to the enlargement of such granular films, the thickness of the polyurea film was slightly increased. On the wafer W, on which the time of the second round of film formation process was 20 minutes, the thickness of the polyurea film 63 became larger than those of the wafers W, on which the times of the second round of film formation process were 0.5 minutes to 10 minutes.

From the results of Evaluation Test 2 as described above, it was confirmed that, when the times of the second round of film formation process were 0.5 minutes to 10 minutes, the formation of film on the polyurea film formed in the first round of film formation process was hindered by the fluorination process performed by the plasma of NF₃ gas. In addition, together with the results of Evaluation Test 1, it was confirmed that the hydrophobicity of the polyurea film is increased by the fluorination process, and the formation of film on the surface of the polyurea film having such a high hydrophobicity is hindered.

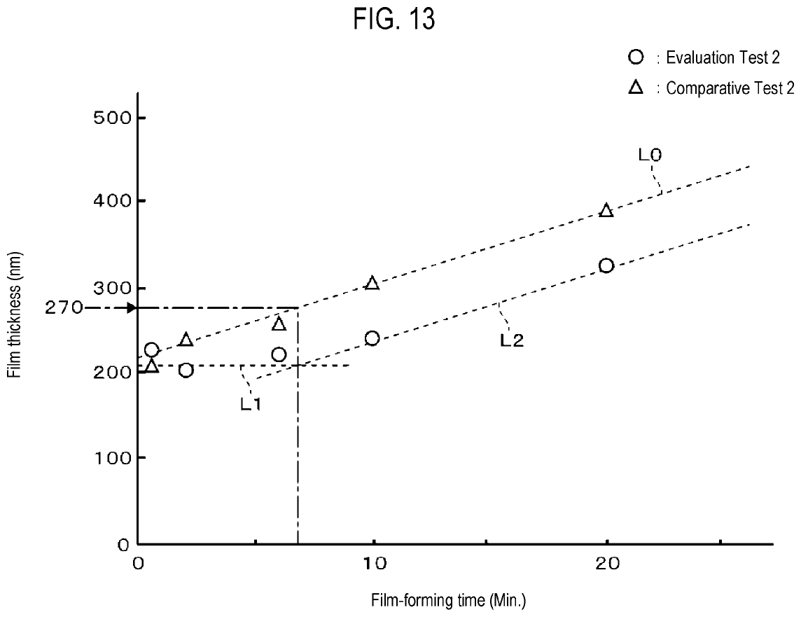

A graph of FIG. 13 collectively shows the results of Evaluation Test 2 and Comparative Test 2. The horizontal axis of the graph represents the time of the second round of film formation process (unit: minutes), and the vertical axis represents the film thickness (unit: nm). In Comparative Test 2, the film thickness increases as the film formation time becomes longer as described above. As shown in the graph, the film thickness and the film formation time have a substantially proportional relationship. An approximate straight line obtained from points indicating the results of Comparative Test 2 is shown as L0.

As described above, in Evaluation Test 2, the film thickness hardly increases while the time of the second round of film formation process is relatively short, whereas the film thickness increases when the time of the second round of film formation process is relatively long. An approximate straight line obtained from the points at which the times of the second round of film formation process are 0.5 minutes, 2 minutes, and 6 minutes at which the increase in the film thickness was hardly observed, is shown as L1, and an approximate straight line obtained from the points at which the times of the second round of film formation process at which the increase in the film thickness was observed, are 10 minutes and 20 minutes, is shown as L2. Each of the approximate straight lines is indicated by a dotted line. The approximate straight line L1 is substantially horizontal, and the slope of the approximate straight line L2 is substantially the same as the approximate straight line L0. The time of the second round of film formation process corresponding to the intersection of the approximate straight lines L1 and L2 was 7 minutes. Accordingly, it is considered that, in Evaluation Test 2, the film thickness increased at the same rate as in Comparative Test 2 after the film formation time of 7 minutes, but there is almost no increase in the film thickness until the film formation time reached 7 minutes. The deposition rates (increase rates of film thicknesses) confirmed from the approximate straight lines L0 and L2 were both 10 nm/min.

Referring to the approximate straight line L0, the film thickness was 270 nm when the film formation time was 7 minutes. That is, it is assumed that polyurea films were formed on both of a polyurea film not processed by the plasma of NF₃ gas and a polyurea film processed by the plasma of NF₃ gas. In that case, it is estimated that the formation of film on the polyurea film processed by the plasma of NF₃ gas is suppressed while the film having a film thickness of 70 nm (=270 nm-200 nm) is formed on the polyurea film not processed by the plasma of NF₃ gas. Therefore, in step R6 in the above-described embodiment, it is preferable to set the reference value related to the cumulative value of the film thickness to, for example, 50 nm, which is 70 nm or less. Further, as described above, it is preferable to perform the fluorination process again when the film formation is performed in the state in which the cumulative value exceeds the reference value.

According to the present disclosure in some embodiments, in forming a film on a substrate by supplying a film-forming gas, it is possible to suppress a film from being formed on an organic film formed in a processing container.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus comprising:
a processing container having an interior that is kept in a vacuum atmosphere;
a stage provided within the processing container and configured to place a substrate thereon;
a first film-forming gas supply part configured to supply a first film-forming gas into the processing container for forming an organic film on a member within the processing container;
a second film-forming gas supply part configured to supply a second film-forming gas into the processing container for forming a film on the substrate; and
a modifying gas supply part configured to supply a modifying gas for modifying the organic film and to suppress a film from being formed on a surface of the organic film by the second film-forming gas.

2. The film forming apparatus of claim 1, further comprising:
a cleaning gas supply part configured to supply a cleaning gas into the processing container so as to remove the organic film,
wherein the supply of the second film-forming gas into the processing container and the supply of the modifying gas into the processing container are repeatedly performed after the cleaning gas is supplied and before the cleaning gas is supplied again.

3. The film forming apparatus of claim 2, further comprising:
a controller configured to output a control signal so as to execute: a pre-coating step of performing a pre-coating on the member by supplying the first film-forming gas into the processing container in a state in which the substrate is not placed on the stage; subsequently, a modifying step of modifying the organic film by supplying the modifying gas into the processing container; and subsequently, a substrate film-forming step of forming the film on the substrate by supplying the second film-forming gas into the processing container in a state in which the substrate is placed on the stage.

4. The film forming apparatus of claim 3, wherein the first film-forming gas and the second film-forming gas include a same material, and
wherein the substrate film-forming step is a step of forming the organic film on the substrate.

5. The film forming apparatus of claim 4, wherein the member on which the pre-coating is performed within the processing container includes at least the stage.

6. The film forming apparatus of claim 5, wherein, when repeating the substrate film-forming step, the controller is configured to determine whether to perform the modifying step again after one round of the substrate film-forming step based on a cumulative value of the film formed on the substrate.

7. The film forming apparatus of claim 6, wherein the modifying gas includes a compound composed of fluorine.

8. The film forming apparatus of claim 1, further comprising:
a controller configured to output a control signal so as to execute: a pre-coating step of performing a pre-coating on the member by supplying the first film-forming gas into the processing container in a state in which the substrate is not placed on the stage; subsequently, a modifying step of modifying the organic film by supplying the modifying gas into the processing container; and subsequently, a substrate film-forming step of forming the film on the substrate by supplying the second film-forming gas into the processing container in a state in which the substrate is placed on the stage.

9. The film forming apparatus of claim 1, wherein the modifying gas includes a compound composed of fluorine.

10. A film forming method comprising:
forming a vacuum atmosphere within a processing container;
placing a substrate on a stage provided within the processing container;
forming an organic film on a member within the processing container by supplying a film-forming gas into the processing container;
forming a film on the substrate by supplying a second film-forming gas into the processing container; and
supplying a modifying gas to modify the organic film and suppress the film from being formed on a surface of the organic film by the second film-forming gas.
